(19) United States
(12) Patent Application Publication
(10) Pub. No.: US 2013/0034951 A1
(43) Pub. Date: Feb. 7, 2013

(54) METHOD OF MANUFACTURING FREE-STANDING GALLIUM NITRIDE SUBSTRATE

(71) Applicants: JunSung Choi, ChungCheongNam-Do (KR); Bongmo Park, ChungCheongNam-Do (KR); Kwangje Woo, ChungCheongNam-Do (KR); Joon Hoi Kim, ChungCheongNam-Do (KR); Cheolmin Park, ChungCheongNam-Do (KR)

(72) Inventors: JunSung Choi, ChungCheongNam-Do (KR); Bongmo Park, ChungCheongNam-Do (KR); Kwangje Woo, ChungCheongNam-Do (KR); Joon Hoi Kim, ChungCheongNam-Do (KR); Cheolmin Park, ChungCheongNam-Do (KR)

(73) Assignee: SAMSUNG CORNING PRECISION MATERIALS CO., LTD.

(21) Appl. No.: 13/559,310

(22) Filed: Jul. 26, 2012

(30) Foreign Application Priority Data
Jul. 26, 2011 (KR) 10-2011-0074053

(51) Int. Cl. H01L 21/20

(52) U.S. Cl. 438/503; 257/E21.119

(57) ABSTRACT

A method of manufacturing a free-standing gallium nitride (GaN) substrate, by which a free-standing GaN substrate can be manufactured without warping or cracks. The method includes the steps of collecting polycrystalline GaN powder that is deposited in a reactor or on a susceptor in a process of growing single crystalline GaN, loading the collected polycrystalline GaN powder into a forming mold, preparing a polycrystalline GaN substrate by sintering the loaded polycrystalline GaN powder, and forming a single crystalline GaN layer by growing single crystalline GaN over the polycrystalline GaN substrate. It is possible to reduce warping and cracks that are caused, due to the difference in the coefficient of thermal expansion, during the growth or cooling of single crystalline GaN in the process of manufacturing the free-standing GaN substrate.

### CROSS REFERENCE TO RELATED APPLICATION

The present application claims priority from Korean Patent Application Number 10-2011-0074053 filed on Jul. 26, 2011, the entire contents of which application are incorporated herein for all purposes by this reference.

### BACKGROUND OF THE INVENTION

1. Field of the Invention

The present invention relates to a method of manufacturing a free-standing gallium nitride (GaN) substrate, and more particularly, to a method of manufacturing a free-standing GaN substrate using polycrystalline GaN powder.

2. Description of Related Art

Recently, studies on compound semiconductors, such as aluminum nitride (AlN), gallium nitride (GaN) or indium nitride (InN), which are used as materials for cutting edge devices, such as light-emitting diodes (LEDs) and laser diodes (LDs), are actively underway.

In particular, since GaN has a very large transition energy bandwidth, it can generate light in the range from ultraviolet (UV) to blue rays. This feature makes GaN an essential next-generation photoelectric material that is used for blue laser diodes (LDs), which are regarded as light sources for next-generation digital versatile discs (DVDs), white light-emitting diodes (LEDs), which can replace the existing illumination devices, high-temperature and high-power electronic devices, and the like.

GaN is grown on a heterogeneous substrate made of sapphire, silicon carbide (SiC), silicon (Si), or the like by, for example, metal-organic chemical vapor deposition (MOCVD) or hydride vapor phase epitaxy (HVPE) because there are no homogeneous substrates that can be practically used for GaN.

In particular, sapphire substrates are widely used because they have a hexagonal structure like GaN, are inexpensive, and are stable at high temperature. However, there are problems, such as bending or cracks, owing to the difference in the lattice constant (13.8%) and the coefficient of thermal expansion (25.5%) between sapphire substrates and GaN.

FIG. 1 is a graph depicting the ratios of the coefficient of thermal expansion of sapphire, SiC and GaAs when the coefficient of thermal expansion of GaN is 1, FIG. 2 is a cross-sectional view depicting warping that is caused by the difference in the coefficient of thermal expansion between a sapphire substrate 10 and a GaN layer 20 when growing the GaN layer, and FIG. 3 is a cross-sectional view depicting warping that is caused by the difference in the coefficient of thermal expansion between the sapphire substrate 10 and the GaN layer 20 when cooling the grown GaN layer. Referring to FIG. 1 to FIG. 3, when growing or cooling the GaN layer, the GaN layer is under stress owing to the difference in the coefficient of thermal expansion between the sapphire substrate and GaN. The GaN layer has problems such as defects or insufficient durability.

In the related art, a free-standing substrate is manufactured by growing a nitride film having a thickness of 300 μm or greater over a sapphire substrate, followed by separating the nitride film from the sapphire substrate using laser.

However, such a method of manufacturing a free-standing substrate has problems in that the nitride film suffers from warping and cracks that are attributable to the difference in the lattice constant and the coefficient of thermal expansion between the heterogeneous substrate (sapphire) and the nitride film as described above. In particular, although a nitride film having a thickness of several hundred micrometers or greater without cracks must be grown in order to manufacture a free-standing substrate having a large diameter of 4″ or greater, it is difficult to grow the nitride film having a thickness of several hundred micrometers or greater without cracks.

In this fashion, when manufacturing a free-standing substrate using the heterogeneous substrate, warping or cracks occur in a nitride film due to the lattice constant mismatch between the heterogeneous substrate and the nitride film or the mismatch in the coefficient of thermal expansion between the heterogeneous substrate and the nitride film. Accordingly, there are problems in that the yield of the manufacture of free-standing substrates is decreased, and that it is difficult to manufacture a free-standing substrate that is thick or has a large-diameter.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of manufacturing a free-standing gallium nitride (GaN) substrate, in which a free-standing GaN substrate can be manufactured without warping or cracks.

In an aspect of the present invention, provided is a method of manufacturing a free-standing GaN substrate. The method includes the steps of: collecting polycrystalline GaN powder that is deposited in a reactor or on a susceptor in a process of growing single crystalline GaN; loading the collected polycrystalline GaN powder into a forming mold; preparing a polycrystalline GaN substrate by sintering the loaded polycrystalline GaN powder; and forming a single crystalline GaN layer by growing single crystalline GaN over the polycrystalline GaN substrate.

In an exemplary embodiment of the invention, the forming mold may be a 2 or 4 inch circular mold.

In another exemplary embodiment of the invention, the step of preparing the polycrystalline GaN substrate may be carried out at a temperature ranging from 1000° C. to 1500° C.

In another exemplary embodiment of the invention, the step of preparing the polycrystalline gallium nitride substrate may be carried out by pressing the loaded polycrystalline gallium nitride powder using a press.

In another exemplary embodiment of the invention, the thickness of the single crystalline gallium nitride layer may range from 300 μm to 1 mm.

According to embodiments of the invention, since the free-standing GaN substrate is manufactured using a polycrystalline GaN substrate, the coefficient of thermal expansion of which is similar to that of single crystalline GaN, it is possible to reduce warping and cracks that are caused, due to the difference in the coefficient of thermal expansion, during the growth or cooling of single crystalline GaN in the process of manufacturing the free-standing GaN substrate. It is also possible to easily manufacture a thick free-standing GaN substrate having a thickness of several hundred micrometers or a large diameter.

In addition, since the polycrystalline GaN powder that is produced in the process of growing single crystalline GaN is reused instead of being discarded, it is possible to manufacture a free-standing GaN substrate more economically and environment-friendly.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a graph depicting the ratios of the coefficient of thermal expansion of sapphire, SiC and GaAs when the coefficient of thermal expansion of GaN is 1;

FIG. 2 is a cross-sectional view depicting warping that is caused by the difference in the coefficient of thermal expansion between a sapphire substrate and GaN when growing a GaN layer;

FIG. 3 is a cross-sectional view depicting warping that is caused by the difference in the coefficient of thermal expansion between the sapphire substrate and GaN when cooling the grown GaN layer; and

FIG. 4 is a schematic flowchart depicting a method of manufacturing a free-standing GaN substrate according to an exemplary embodiment of the invention.

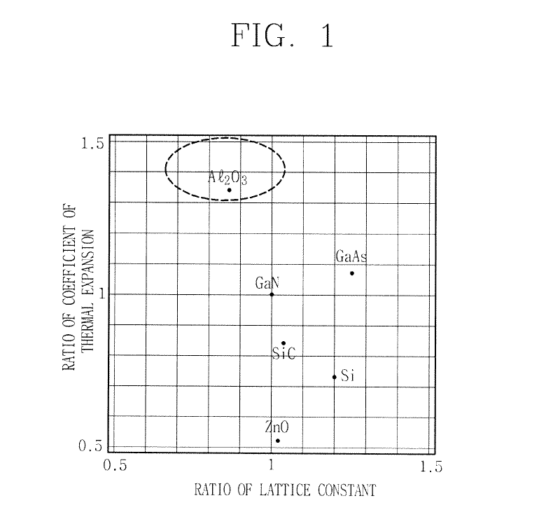

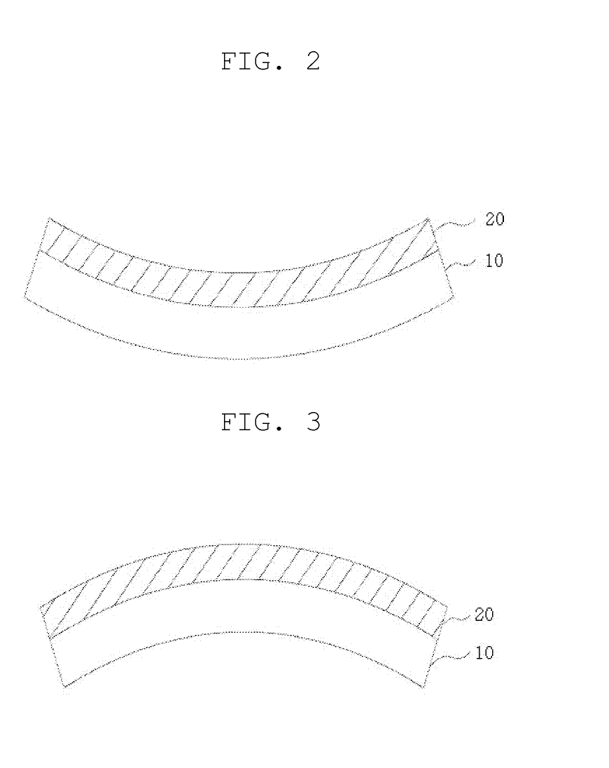

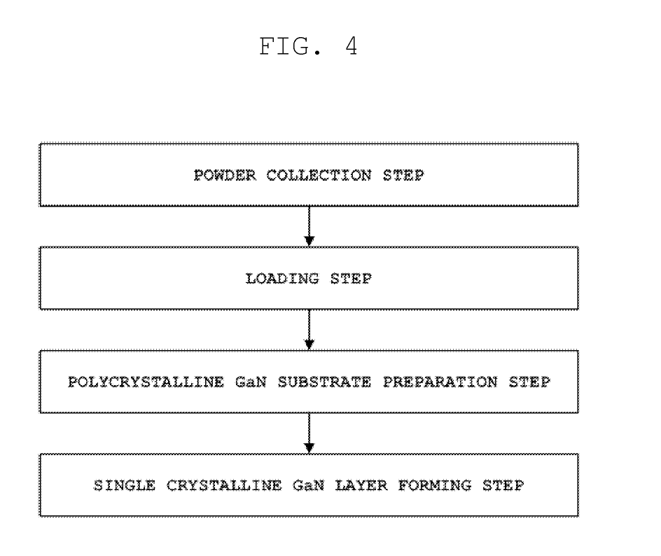

### DETAILED DESCRIPTION OF THE INVENTION

Reference will now be made in detail to a method of manufacturing a free-standing gallium nitride (GaN) substrate according to the invention, embodiments of which are illustrated in the accompanying drawings and described below.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

FIG. 4 is a schematic flowchart depicting a method of manufacturing a free-standing GaN substrate according to an exemplary embodiment of the invention.

Referring to FIG. 4, the method of manufacturing a free-standing GaN substrate of this embodiment includes a powder collection step, a loading step, a polycrystalline GaN substrate preparation step, and a single crystalline GaN layer forming step.

In order to manufacture a free-standing GaN substrate, first, polycrystalline GaN powder is collected.

The polycrystalline GaN powder may be collected by scraping the polycrystalline GaN powder that is deposited on a reactor, a susceptor or the like in the process of growing single crystalline GaN.

In general, the growth of single crystalline GaN is performed by one of methods, including metal-organic chemical vapor deposition (MOCVD) and hydride vapor phase epitaxy (HVPE). In particular, HVPE has the merit in that it grows GaN faster than MOCVD.

Such methods of growing single crystalline GaN have a common process in which a reactant gas that is input into the reactor undergoes a chemical reaction on the surface of the substrate, so that single crystalline GaN is grown over the substrate.

Here, the reactant gas is not only grown as a single crystalline GaN layer over the surface of the substrate by the chemical reaction, but also deposited as polycrystalline GaN on the wall of the reactor or on the suscepter that supports the substrate.

That is, the polycrystalline GaN powder collection step of this embodiment may be implemented by collecting powder that is deposited in the reactor or on the susceptor as described above.

Afterwards, the polycrystalline GaN powder that is collected from the reactor or the susceptor is loaded into a forming mold.

The size and shape of the forming mold may be implemented as a variety of forms depending on the shape of a free-standing GaN substrate that is to be manufactured. In general, it is preferred that the forming mold be a 2 or 4 inch circular mold.

Afterwards, a polycrystalline GaN substrate is prepared by loading the forming mold into a sintering furnace, followed by sintering.

When the polycrystalline GaN powder loaded into the forming mold is sintered in the sintering furnace by pressing it at a predetermined temperature, the polycrystalline GaN powder is recrystallized. After that, the recrystallized polycrystalline GaN powder is cooled to room temperature and is then removed from the forming mold, thereby completing the manufacture of a polycrystalline GaN substrate.

Here, the sintering is performed at a temperature, preferably, ranging from 1000° C. to 1500° C., and the pressing may be performed using a press, which presses the polycrystalline GaN powder that is loaded in the forming mold.

Finally, single crystalline GaN is grown over the polycrystalline GaN substrate, thereby forming a single crystalline GaN layer, which will be used in the manufacture of a free-standing GaN substrate.

The method of growing single crystalline GaN over the polycrystalline GaN substrate may be implemented as a variety of methods, such as MOCVD or HVPE.

Here, it is preferred that the thickness of the single crystalline GaN layer range from 300 μm to 1 mm.

Since the free-standing GaN substrate is manufactured using a polycrystalline GaN substrate, the coefficient of thermal expansion of which is similar to that of single crystalline GaN, it is possible to reduce warping and cracks that are caused, due to the difference in the coefficient of thermal expansion, during the growth or cooling of single crystalline GaN in the process of manufacturing the free-standing GaN substrate. It is also possible to easily manufacture a thick free-standing GaN substrate having a thickness of several hundred micrometers or a large diameter.

In addition, since the polycrystalline GaN powder that is produced in the process of growing single crystalline GaN is reused instead of being discarded, it is possible to manufacture a free-standing GaN substrate more economically and environment-friendly.

Furthermore, the free-standing GaN substrate, which is manufactured by the invention, can replace Si or sapphire that is used as an LED substrate.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of manufacturing a free-standing gallium nitride substrate, comprising:
collecting polycrystalline gallium nitride powder that is deposited in a reactor or on a susceptor in a process of growing single crystalline gallium nitride;
loading the collected polycrystalline gallium nitride powder into a forming mold;
preparing a polycrystalline gallium nitride substrate by sintering the loaded polycrystalline gallium nitride powder; and
forming a single crystalline gallium nitride layer by growing single crystalline gallium nitride over the polycrystalline gallium nitride substrate.

2. The method of claim 1, wherein the forming mold comprises a circular mold having a diameter of 2 or 4 inches.

3. The method of claim 1, wherein preparing the polycrystalline gallium nitride substrate is carried out at a temperature ranging from 1000° C. to 1500° C.

4. The method of claim 1, wherein preparing the polycrystalline gallium nitride substrate comprises pressing the loaded polycrystalline gallium nitride powder using a press.

5. The method of claim 1, wherein a thickness of the single crystalline gallium nitride layer ranges from 300 μm to 1 mm.
